(19) United States
(12) Patent Application Publication
(10) Pub. No.: US 2026/0193772 A1
(43) Pub. Date: Jul. 9, 2026

(54) SUBSTRATE PROCESSING METHOD AND SUBSTRATE PROCESSING APPARATUS

(71) Applicant: Tokyo Electron Limited, Tokyo (JP)

(72) Inventors: Shuji AZUMO, Yamanashi (JP); Takashi FUSE, Tokyo (JP); Shinichi IKE, Yamanashi (JP)

(21) Appl. No.: 19/560,559

(22) Filed: Mar. 9, 2026

Related U.S. Application Data
(63) Continuation of application No. PCT/JP2024/031279, filed on Aug. 30, 2024.

(30) Foreign Application Priority Data
Sep. 20, 2023 (JP) 2023-152540

(51) Int. Cl. C23C 16/04; C23C 16/458; C23C 16/52

(52) U.S. Cl. CPC C23C 16/04; C23C 16/4583; C23C 16/52

(57) ABSTRACT

A substrate processing method and a substrate processing apparatus for selectively forming a blocking layer are provided. The substrate processing method includes: (a) preparing a substrate having a first surface including a dielectric film, a second surface including a metal nitride film, and a third surface including a conductive film, in different regions of a substrate surface; (b) supplying a first organic compound containing a thiol group, a phosphonic acid group, or a carboxylic acid group as a first reactive group to the substrate; and (c) supplying a second organic compound containing a carbon-carbon double bond or a carbon-carbon triple bond as a second reactive group to the substrate, wherein a blocking layer is formed on the second surface and the third surface selectively with respect to the first surface.

### CROSS-REFERENCE TO RELATED APPLICATIONS

This application is a continuation application of International Application No. PCT/JP2024/031279, filed on August 30, 2024, and designating the U.S., which is based upon and claims priority to Japanese Patent Application No. 2023-152540, filed on September 20, 2023, the entire contents of which are incorporated herein by reference.

### BACKGROUND

### Technical Field

The present disclosure relates to a substrate processing method and a substrate processing apparatus.

### Background Art

U.S. Patent Application Publication No. 2020/347493 discloses a method for forming a blocking layer, including a step of exposing a substrate containing a metal material having a first surface and a non-metal material having a second surface to an unsaturated hydrocarbon, to selectively form a blocking layer on the first surface rather than on the second surface.

### SUMMARY

In order to solve the above problem, one embodiment provides a substrate processing method, including: (a) preparing a substrate having a first surface including a dielectric film, a second surface including a metal nitride film, and a third surface including a conductive film, in different regions of a substrate surface; (b) supplying a first organic compound containing any one of a thiol group, a phosphonic acid group, or a carboxylic acid group as a first reactive group to the substrate; and (c) supplying a second organic compound containing a carbon-carbon double bond or a carbon-carbon triple bond as a second reactive group to the substrate, wherein a blocking layer is formed on the second surface and the third surface selectively with respect to the first surface.

### BRIEF DESCRIPTION OF THE DRAWINGS

FIG. 1 is a schematic cross-sectional view showing an example of a substrate processing apparatus according to an embodiment;

FIG. 2 is a flowchart showing an example of a substrate processing method according to a first embodiment;

FIG. 3A is an example of a schematic cross-sectional view showing a state of a substrate in each step of a substrate processing method according to the first embodiment;

FIG. 3B is an example of a schematic cross-sectional view showing a state of the substrate in each step of the substrate processing method according to the first embodiment;

FIG. 3C is an example of a schematic cross-sectional view showing a state of the substrate in each step of the substrate processing method according to the first embodiment;

FIG. 4A is an example of a schematic cross-sectional view showing a state of the substrate in each step of the substrate processing method according to the first embodiment;

FIG. 4B is an example of a schematic cross-sectional view showing a state of the substrate in each step of the substrate processing method according to the first embodiment;

FIG. 4C is an example of a schematic cross-sectional view showing a state of the substrate in each step of the substrate processing method according to the first embodiment;

FIG. 5 is a flowchart showing an example of a substrate processing method according to a second embodiment;

FIG. 6A is an example of a schematic cross-sectional view showing a state of a substrate in each step of the substrate processing method according to the second embodiment;

FIG. 6B is an example of a schematic cross-sectional view showing a state of the substrate in each step of the substrate processing method according to the second embodiment;

FIG. 6C is an example; of a schematic cross-sectional view showing a state of the substrate in each step of the substrate processing method according to the second embodiment;

FIG. 7A is an example of a schematic cross-sectional view showing the state of a substrate in each step of the substrate processing method according to the second embodiment;

FIG. 7B is an example of a schematic cross-sectional view showing a state of the substrate in each step of the substrate processing method according to the second embodiment;

FIG. 7C is an example of a schematic cross-sectional view showing a state of the substrate in each step of the substrate processing method according to the second embodiment; and

FIG. 8 is an example of a schematic cross-sectional view showing a state of a substrate in a substrate processing method according to a reference example.

### DETAILED DESCRIPTION OF THE INVENTION

Non-limiting exemplary embodiments of the present disclosure will be described below with reference to the accompanying drawings. In all of the accompanying drawings, the same or corresponding members or parts are denoted by the same or corresponding reference numerals, and redundant descriptions thereof will be omitted.

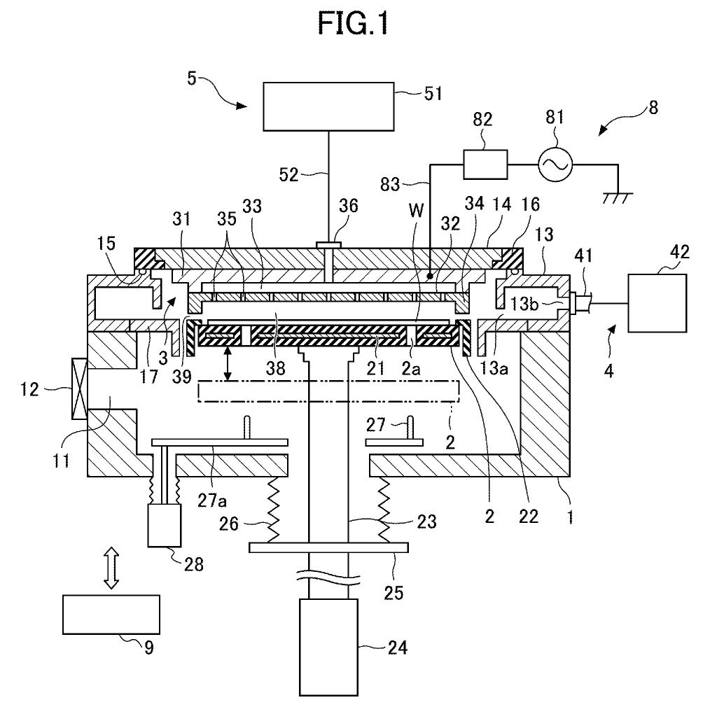

An example of a substrate processing apparatus according to an embodiment will be described with reference to FIG. 1. FIG. 1 is a schematic cross-sectional view showing an example of a substrate processing apparatus according to an embodiment. The substrate processing apparatus includes a processing vessel 1, a mounting table 2, a showerhead 3, a gas exhaust 4, a gas supply 5, an RF power supply 8, a controller 9, and the like.

The processing vessel 1 is composed of a metal, such as aluminum and the like, and has a substantially cylindrical shape. The processing vessel 1 accommodates a substrate W, such as a wafer and the like. A loading/unloading port 11 through which the substrate W is loaded or unloaded is formed in a side wall of the processing vessel 1. The loading/unloading port 11 is opened and closed by a gate valve 12. An annular gas exhaust duct 13 having a rectangular cross-sectional shape is provided on the body part of the processing vessel 1. A slit 13a is formed in the gas exhaust duct 13 along an inner circumferential surface of the gas exhaust duct 13. A gas exhaust port 13b is formed in an outer wall of the gas exhaust duct 13. A top wall 14 is provided on an upper surface of the gas exhaust duct 13 via an insulator member 16 to close an upper opening of the processing vessel 1. The gap between the gas exhaust duct 13 and the insulator member 16 is airtightly sealed by a seal ring 15. A partitioning member 17 partitions the interior of the processing vessel 1 into an upper section and a lower section when the mounting table 2 (and a cover member 22) is raised to a processing position described later.

The mounting table (substrate support) 2 horizontally supports (holds) the substrate W in the processing vessel 1. The mounting table 2 is formed in a disk shape having a size corresponding to the substrate W, and is supported by a support member 23. The mounting table 2 is composed of a ceramic material, such as AlN and the like, or a metal material, such as aluminum, nickel alloy, and the like, and a heater 21 for heating the substrate W is embedded in the mounting table 2. The heater 21 is supplied with power from a heater power source (not shown) to generate heat. Then, by controlling the output from the heater 21 in accordance with a temperature signal from a thermocouple (not shown) provided near the upper surface of the mounting table 2, the substrate W is controlled to a predetermined temperature. The mounting table 2 is provided with the cover member 22 composed of a ceramic material, such as alumina and the like, to cover the outer peripheral region of the upper surface of the mounting table 2 and the side surface of the mounting table 2.

The support member 23 for supporting the mounting table 2 is provided on the bottom surface of the mounting table 2. The support member 23 extends from the center of the bottom surface of the mounting table 2 to the lower side of the processing vessel 1 through a hole formed in the bottom wall of the processing vessel 1, and the lower end of the support member 23 is connected to a lifting mechanism 24. The lifting mechanism 24 raises and lowers the mounting table 2 via the support member 23 between a processing position shown in FIG. 1 and a conveying position under the processing position, indicated by a two-dot chain line, at which the substrate W can be conveyed. A flange 25 is attached to the support member 23 under the processing vessel 1. A bellows 26 is provided between the bottom surface of the processing vessel 1 and the flange 25. The bellows 26 partitions the atmosphere in the processing vessel 1 from the open air, and extends and contracts along with the lifting operation of the mounting table 2.

Near the bottom surface of the processing vessel 1, three (only two shown) wafer support pins 27 are provided to project upward from a lifting plate 27a. A lifting mechanism 28 provided under the processing vessel 1 raises and lowers the wafer support pins 27 via the lifting plate 27a. The wafer support pins 27 are inserted through through-holes 2a provided in the mounting table 2 that is at the conveying position, and can be projected from and retracted into the upper surface of the mounting table 2. By raising and lowering the wafer support pins 27, the substrate W is conveyed between a conveying mechanism (not shown) and the mounting table 2.

The showerhead 3 supplies a processing gas into the processing vessel 1 in the form of a shower. The showerhead 3 is composed of a metal and provided to face the mounting table 2, and has a diameter almost equal to that of the mounting table 2. The showerhead 3 includes a body part 31 and a shower plate 32. The body part 31 is fixed to the top wall 14 of the processing vessel 1. The shower plate 32 is connected under the body part 31. A gas diffusion space 33 is formed between the body part 31 and the shower plate 32. The gas diffusion space 33 is provided with a gas introduction hole 36 to penetrate the center of the top wall 14 of the processing vessel 1 and the body part 31. An annular projection 34 projecting downward is formed at the periphery of the shower plate 32. Gas discharge holes 35 are formed in a flat part inside the annular projection 34. When the mounting table 2 is present at the processing position, a processing space 38 is formed between the mounting table 2 and the shower plate 32, and the upper surface of the cover member 22 and the annular projection 34 are close to each other to form an annular gap 39.

The gas exhaust 4 exhausts any gas in the interior of the processing vessel 1. The gas exhaust 4 includes a gas exhaust pipe 41 connected to the gas exhaust port 13b, and a gas exhaust mechanism 42 connected to the gas exhaust pipe 41 and including a vacuum pump, a pressure control valve, and the like. In a process, a gas in the processing vessel 1 reaches the gas exhaust duct 13 through the slit 13a, and is exhausted by the gas exhaust mechanism 42 from the gas exhaust duct 13 through the gas exhaust pipe 41.

The gas supply 5 supplies various processing gases to the showerhead 3. The gas supply 5 includes a gas source 51 and a gas line 52. The gas source 51 includes, for example, supply sources of various processing gases, mass flow controllers, and valves (none of which are shown). The various processing gases are introduced from the gas source 51 into the gas diffusion space 33 through the gas line 52 and the gas introduction hole 36.

The substrate processing apparatus is a capacitively coupled plasma apparatus, in which the mounting table 2 functions as a lower electrode and the showerhead 3 functions as an upper electrode. The mounting table 2 is grounded via a capacitor (not shown). However, the mounting table 2 may be grounded without a capacitor, or may be grounded via a circuit in which a capacitor and a coil are combined. The showerhead 3 is connected to the RF power supply 8.

The RF power supply 8 supplies high-frequency power (hereinafter also referred to as “RF power”) to the showerhead 3. The RF power supply 8 includes an RF power source 81, a matcher 82, and a power supply line 83. The RF power source 81 is a power source for generating RF power. The RF power has a frequency suitable for forming a plasma. The frequency of the RF power is, for example, a frequency within the range of 450 KHz in a low frequency band to 2.45 GHz in a microwave band. The RF power source 81 is connected to the body part 31 of the showerhead 3 via the matcher 82 and the power supply line 83. The matcher 82 includes a circuit for matching the impedance of a load with the internal impedance of the RF power source 81. Although the RF power supply 8 has been described as supplying RF power to the showerhead 3 serving as the upper electrode, this is non-limiting. The RF power supply 8 may supply the RF power to the mounting table 2 serving as the lower electrode.

The controller 9 is, for example, a computer, and includes a Central Processing Unit (CPU), a Random Access Memory (RAM), a Read Only Memory (ROM), an auxiliary storage device, and the like. The CPU operates based on a program stored in the ROM or the auxiliary storage device, and controls the operation of the substrate processing apparatus. The controller 9 may be provided inside or outside the substrate processing apparatus. When the controller 9 is provided outside the substrate processing apparatus, the controller 9 can control the substrate processing apparatus by a communication method, such as a wired or wireless communication method and the like.

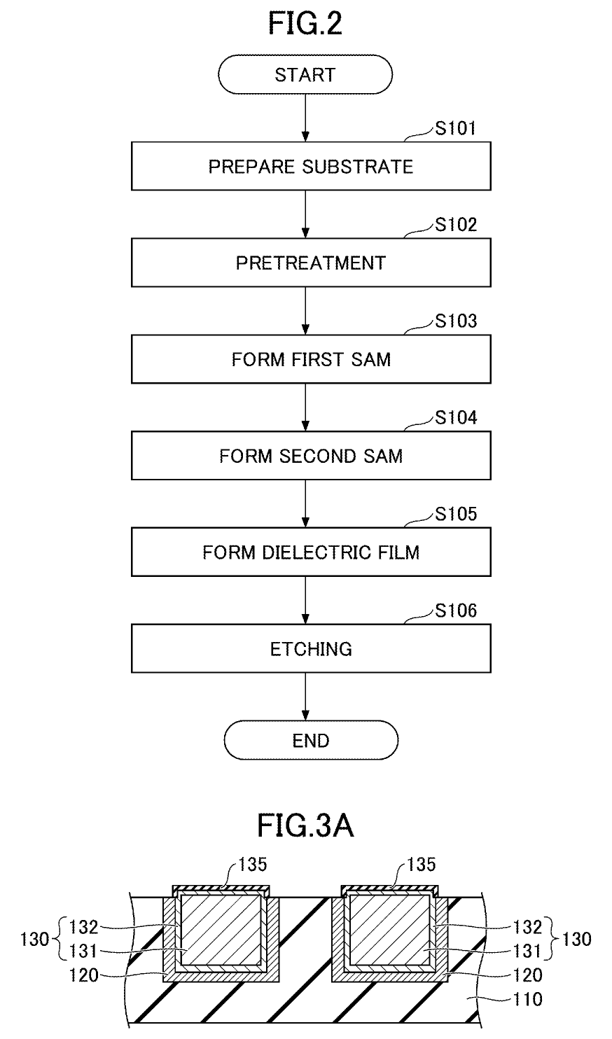

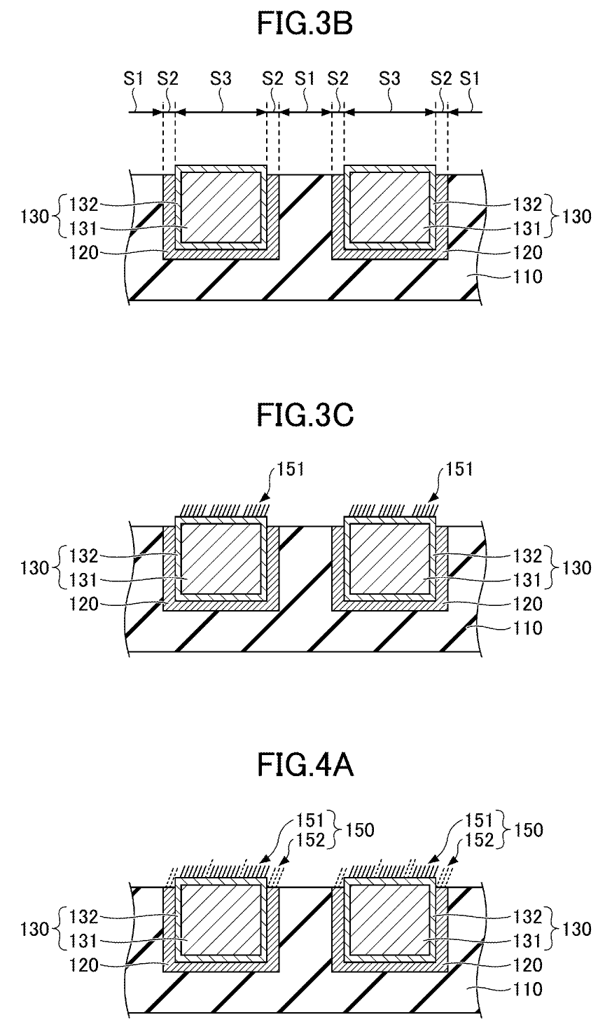

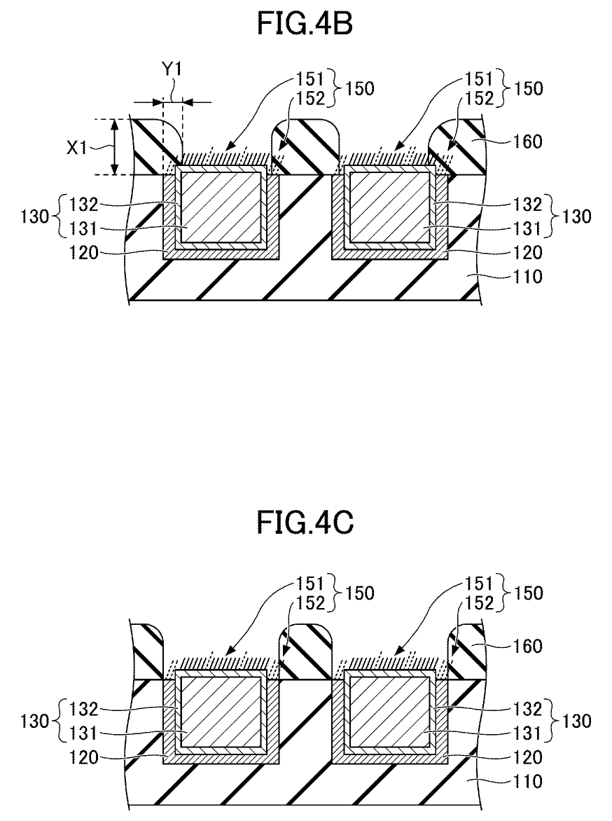

Next, an example of the substrate processing method according to the present embodiment will be described with reference to FIGS. 2 to 4C. FIG. 2 is a flowchart showing an example of the substrate processing method according to a first embodiment. FIGS. 3A to 3C and FIGS. 4A to 4C are examples of schematic cross-sectional views showing the state of the substrate W in each step of the substrate processing method according to the first embodiment.

In step S101, the controller 9 prepares the substrate W. The controller 9 controls the lifting mechanism 24 to lower the mounting table 2 to the conveying position, and opens the gate valve 12. Subsequently, a conveying arm (not shown) loads the substrate W into the processing vessel 1 via the loading/unloading port 11, and places the substrate W on the mounting table 2 heated to a predetermined temperature by the heater 21. Subsequently, the controller 9 controls the lifting mechanism 24 to raise the mounting table 2 to the processing position, and depressurizes the interior of the processing vessel 1 to a predetermined degree of vacuum by the gas exhaust mechanism 42.

An example of a schematic cross-sectional view of the prepared substrate W will be described with reference to FIG. 3A. FIG. 3A is an example of a schematic cross-sectional view of the substrate W prepared in step S101. The substrate W includes a dielectric film 110, a barrier metal film 120, and a conductive film 130.

The dielectric film 110 is composed of a dielectric material (insulating material) containing silicon (Si). Specifically, the dielectric film 110 may be any one of SiO, SiN, SiC, SiOC, SiCN, SiOCN, or the like. The dielectric film 110 may be a film of any one of the above that is doped with an impurity. The dielectric film 110 may be composed of a dielectric material (insulating material) containing aluminum (Al) or the like in addition to silicon (Si).

The barrier metal film 120 is provided between the dielectric film 110 and the conductive film 130, and is composed of a metal nitride film. Specifically, the barrier metal film 120 may be any one of TaN, TiN, or the like.

The conductive film 130 is composed of a conductive material, such as a metal and the like. The conductive film 130 shown in FIG. 3A includes a conductive layer 131 and a liner layer 132 covering the conductive layer 131. The conductive layer 131 is composed of, for example, Cu. The liner layer 132 is provided to cover the conductive layer 131, and is composed of, for example, Co. Although the conductive film 130 has been described as including the conductive layer 131 and the liner layer 132, this is non-limiting. The conductive film 130 may be composed only of the conductive layer 131 without the liner layer 132. The conductive film 130 may be composed of, for example, any one of Cu having a Co-covered surface, Cu, Co, Ru, W, or the like. An oxide layer 135 resulting from oxidation due to natural oxidation or the like is formed on the exposed part of the conductive film 130 (and the liner layer 132).

In step S102, the controller 9 performs a pretreatment on the substrate W. Here, the pretreatment is a pretreatment for forming a blocking layer 150 (see FIG. 4A described later) or a dielectric film 160 (see FIG. 4B described later). The pretreatment includes, for example, removal of the oxide layer 135 formed on the surface of the conductive film 130 (reduction treatment), removal of contaminants adhering to the surface of the substrate W, and the like.

For example, the controller 9 controls the gas supply 5 to supply H₂ gas into the processing space 38, controls the RF power supply 8 to form a plasma in the processing space 38, and applies a reduction treatment to the substrate W with a hydrogen plasma. Thus, the oxide layer 135 is removed from the surface of the conductive film 130. When the surface of the substrate W is clean (has scarce metal oxide layer or scarce adherent contaminants), the pretreatment does not need to be performed.

FIG. 3B is an example of a schematic cross-sectional view of the substrate W after the process in step S102. As shown in FIG. 3B, the substrate surface of the substrate W is, for example, the upper surface of the substrate W. The substrate W has a first surface S1 including the dielectric film 110, a second surface S2 including the barrier metal film 120, and a third surface S3 including the conductive film 130 in different regions of the substrate surface.

In step S103, the controller 9 forms a first self-assembled monolayer (SAM) 151 (hereinafter, also referred to as the first SAM 151) on the substrate W.

For example, the controller 9 controls the gas supply 5 to supply a first organic compound gas into the processing space 38, thereby exposing the substrate W to the first organic compound gas.

The first organic compound gas contains a first main chain composed of a hydrocarbon and a first reactive group formed at one end of the first main chain. The first reactive group is a reactive group that selectively adsorbs to (bonds with) the third surface S3. That is, the first reactive group is a reactive group that adsorbs to (bonds with) the third surface S3 selectively with respect to the first surface S1, and adsorbs to (bonds with) the third surface S3 selectively with respect to the second surface S2. The first organic compound gas may be any one of a thiol-based compound, a phosphonic acid-based compound, a carboxylic acid-based compound, or the like.

The thiol-based compound is represented by a general formula “R-SH”. R is, for example, a hydrocarbon group, or a hydrocarbon group in which at least one hydrogen atom is replaced with fluorine, and corresponds to the first main chain. The SH group is formed at one end of the first main chain, and corresponds to the first reactive group. Specific examples of the thiol-based compound include CH₃(CH₂)ₓCH₂SH (X is an integer of 0 to 18).

The phosphonic acid-based compound is represented by a general formula “R-P(=O)(OH)₂”. R is, for example, a hydrocarbon group, or a hydrocarbon group in which at least one hydrogen atom is replaced with fluorine, and corresponds to the first main chain. The P(=O)(OH)₂ group is formed at one end of the first main chain, and corresponds to the first reactive group. Specific examples of the phosphonic acid-based compound include CH₃(CH₂)ₓCH₂P(=O)(OH)₂ (X is an integer of 0 to 18).

The carboxylic acid-based compound is represented by a general formula “R-COOH”. R is, for example, a hydrocarbon group, or a hydrocarbon group in which at least one hydrogen atom is replaced with fluorine, and corresponds to the first main chain. The COOH group is formed at one end of the first main chain, and corresponds to the first reactive group. Specific examples of the carboxylic acid-based compound include CH₃(CH₂)ₓCH₂COOH (X is an integer of 0 to 18), propionic acid (CH₃CH₂COOH), and octanoic acid (CH₃(CH₂)₆COOH).

FIG. 3C is an example of the schematic cross-sectional view of the substrate W after the process of step S103. As shown in FIG. 3C, the first reactive group of the first organic compound gas adsorbs to the third surface S3, and the first main chain is oriented in accordance with the interaction between the first main chains, thereby forming the first SAM 151. That is, the first SAM 151 is formed on the third surface S3 of the conductive film 130.

In step S104, the controller 9 forms a second self-assembled monolayer 152 (hereinafter, also referred to as the second SAM 152) on the substrate W.

For example, the controller 9 controls the gas supply 5 to supply a second organic compound gas different from the first organic compound gas into the processing space 38, thereby exposing the substrate W to the second organic compound gas.

The second organic compound gas contains a second main chain composed of a hydrocarbon, and a second reactive group formed at one end of the second main chain. The second reactive group is a reactive group that selectively adsorbs to (bonds with) at least the second surface S2. That is, the second reactive group is a reactive group that adsorbs to (bonds with) the second surface S2 selectively with respect to the first surface S1. The second reactive group is a reactive group that selectively adsorbs to (bonds with) the second surface S2 and the third surface S3. That is, the second reactive group is a reactive group that adsorbs to (bonds with) the second surface S2 selectively with respect to the first surface S1, and adsorbs to (bonds with) the third surface S3 selectively with respect to the first surface S1. An olefin-based compound can be used as the second organic compound gas.

The olefin-based compound is represented by a general formula “R-C=CH₂” or “R-C≡CH”. R is, for example, a hydrocarbon group, or a hydrocarbon group in which at least one hydrogen atom is replaced with fluorine, and corresponds to the second main chain. The second reactive group is formed at one end of the second main chain, and contains a C-C double bond or triple bond. Specific examples of the olefin-based compound include CH₃(CH₂)ₓCH=CH₂ (X is an integer of 0 to 18) and CH₃(CH₂)ₓC≡CH (X is an integer of 0 to 18).

FIG. 4A is an example of a schematic cross-sectional view of the substrate W after the process of step S104. As shown in FIG. 4A, the second reactive group of the second organic compound gas adsorbs to the second surface S2 and the third surface S3, and the second main chain is oriented in accordance with the interaction between the second main chains, thereby forming the second SAM 152. That is, the second SAM 152 is formed on the second surface S2 of the barrier metal film 120 and the third surface S3 of the conductive film 130.

The first SAM 151 formed in step S103 and the second SAM 152 formed in step S104 constitute the blocking layer 150. That is, in the processes shown in steps S103 and S104, the blocking layer 150 is formed on the second surface S2 and the third surface S3 selectively with respect to the first surface S1.

As described above, according to the substrate processing method according to the first embodiment, the blocking layer 150 can be selectively formed on the second surface S2 and the third surface S3 as shown in steps S101 to S104.

Next, in step S105, the controller 9 forms the dielectric film 160 on the substrate W. Here, the dielectric film 160 may be any one of SiO, SiO containing Al, or the like.

For example, the controller 9 controls the gas supply 5 to alternately supply a metal-containing catalyst gas and a silicon precursor gas into the processing space 38, thereby forming the dielectric film 160 on the first surface S1 in which the dielectric film 110 is formed.

The metal-containing catalyst gas may be trimethylaluminum (TMA) gas. The TMA gas adsorbs to the first surface S1 in which the dielectric film 110 is formed selectively with respect to the second surface S2 and the third surface S3 on which the blocking layer 150 is formed.

Tris (tert-pentoxy) silanol (TPSOL) gas can be used as the silicon precursor gas. Tris (tert-pentoxy) silanol) gas can be used. The silicon precursor gas reacts with the metal-containing catalyst that adsorbs to the first surface S1, to form a silicon oxide film. Thus, the dielectric film 160 is formed on the first surface S1 in which the dielectric film 110 is formed, selectively with respect to the second surface S2 and the third surface S3 on which the blocking layer 150 is formed.

FIG. 4B is an example of a schematic cross-sectional view of the substrate W after the process in step S105. The dielectric film 160 is formed isotropically. That is, as shown in FIG. 4B, the dielectric film 160 grows from the first surface S1 in the film thickness direction and also grows in the lateral direction. Therefore, the dielectric film 160 is formed to overhang the conductive film 130.

In step S106, the controller 9 performs etching treatment on the substrate W. The etching treatment is preferably dry etching, and may be, for example, Chemical Oxide Removal (COR).

For example, the controller 9 controls the gas supply 5 to supply etching gas (for example, mixed gas of HF gas and NH₃ gas, plasma NF₃ gas, alternate supply of TMA gas and HF gas, and the like) into the processing space 38 to etch a part of the dielectric film 160.

FIG. 4C is a schematic cross-sectional view of the substrate W after the process in step S106. Here, the dielectric film 160 formed on the second surface S2 and the third surface S3 has a low etching resistance because of including the blocking layer 150 (the first SAM 151 and the second SAM 152). That is, the amount by which the dielectric film 160 formed on the second surface S2 and the third surface S3 is etched in the lateral direction is greater than the amount by which the dielectric film 160 formed on the first surface S1 is etched in the film thickness direction. Therefore, the dielectric film 160 on the second surface S2 and the third surface S3 is suitably removed.

As described above, according to the substrate processing method according to the first embodiment, the dielectric film 160 can be selectively formed on the dielectric film 110 as shown in the processes from step S101 to step S106.

The processes from step S102 to step S106 or the processes from step S103 to step S106 may be repeated as one cycle. Thus, the film thickness of the dielectric film 160 formed on the first surface S1 can be increased.

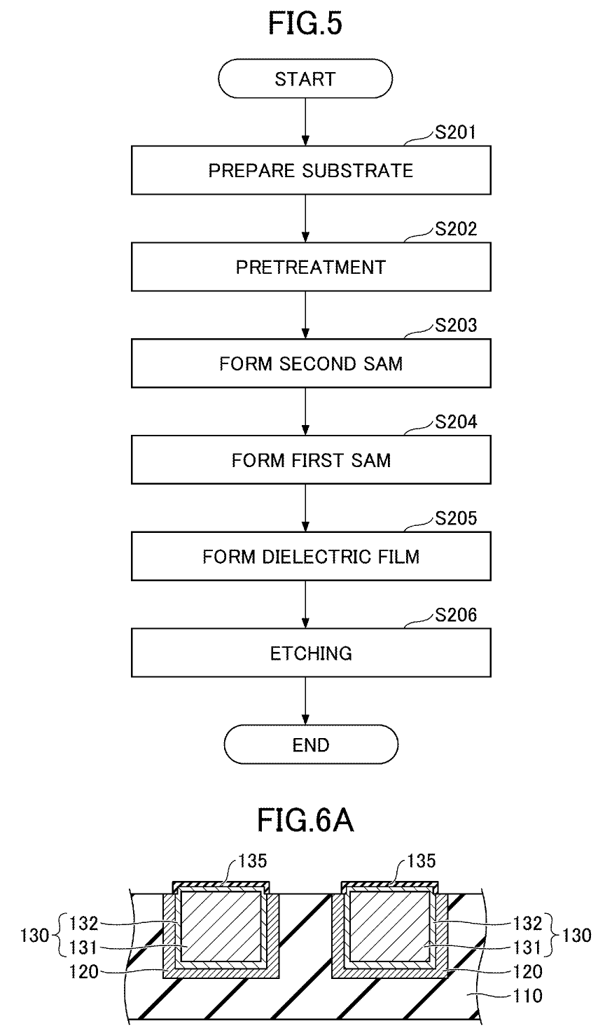

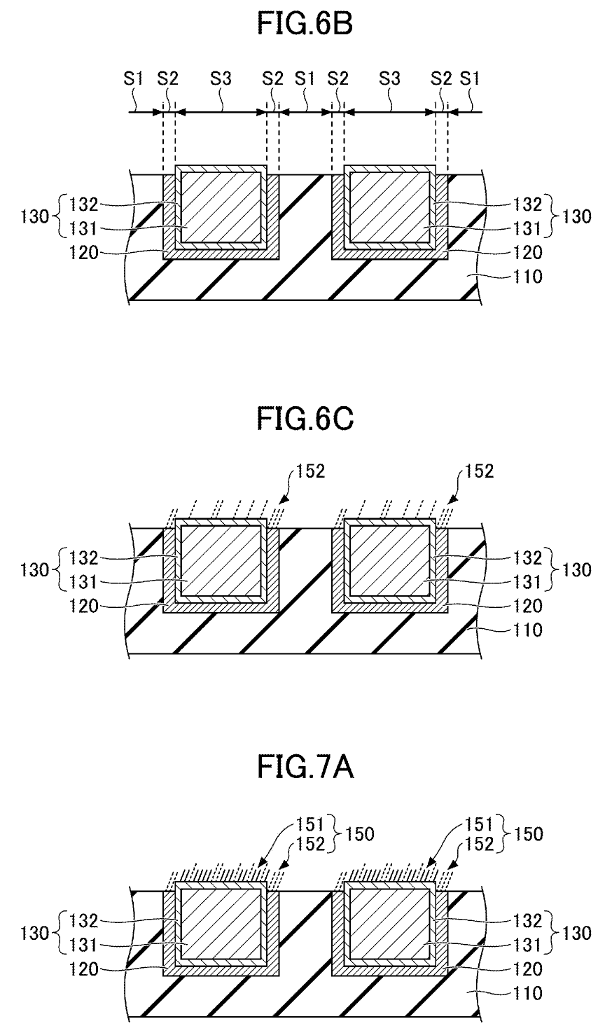

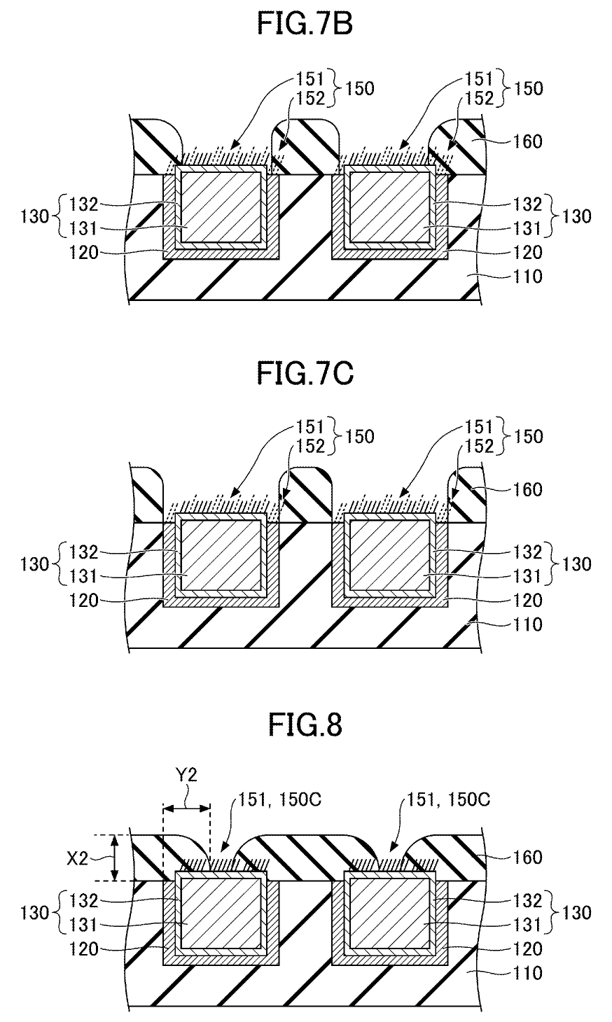

Next, another example of the substrate processing method according to the present embodiment will be described with reference to FIGS. 5 to 7C. FIG. 5 is a flowchart showing an example of the substrate processing method according to a second embodiment. FIGS. 6A to 6C and FIGS. 7A to 7C are examples of schematic cross-sectional views showing the state of the substrate W in each step of the substrate processing method according to the second embodiment.

In step S201, as in step S101, the controller 9 prepares the substrate W. FIG. 6A is a schematic cross-sectional view of the substrate W prepared in step S201. The substrate W includes a dielectric film 110, a barrier metal film 120, and a conductive film 130.

In step S202, as in step S102, the controller 9 performs a pretreatment on the substrate W. FIG. 6B is a schematic cross-sectional view of the substrate W after the process in step S202. The substrate W includes a first surface S1 including the dielectric film 110, a second surface S2 including the barrier metal film 120, and a third surface S3 including the conductive film 130 in different regions of the substrate surface.

In step S203, the controller 9 forms a second self-assembled monolayer (second SAM) 152 on the substrate W.

For example, as in step S104, the controller 9 controls the gas supply 5 to supply the second organic compound gas into the processing space 38, thereby exposing the substrate W to the second organic compound gas.

FIG. 6C is an example of a schematic cross-sectional view of the substrate W after the process in step S203. As shown in FIG. 6C, the second reactive group of the second organic compound gas adsorbs to the second surface S2 and the third surface S3, and the second main chain is oriented in accordance with the interaction between the second main chains, thereby forming the second SAM 152. That is, the second SAM 152 is formed on the second surface S2 of the barrier metal film 120 and the third surface S3 of the conductive film 130.

In step S204, the controller 9 forms a first self-assembled monolayer (first SAM) 151 on the substrate W.

For example, as in step S103, the controller 9 controls the gas supply 5 to supply the first organic compound gas into the processing space 38, thereby exposing the substrate W to the first organic compound gas.

FIG. 7A is an example of a schematic cross-sectional view of the substrate W after the process in step S204. As shown in FIG. 7A, the first reactive group of the first organic compound gas adsorbs to the third surface S3, and the first main chain is oriented in accordance with the interaction between the first main chains, thereby forming the first SAM 151. That is, the first SAM 151 is formed on the third surface S3 of the conductive film 130.

The second SAM 152 formed in step S203 and the first SAM 151 formed in step S204 constitute the blocking layer 150. That is, in the processes shown in steps S203 and S204, the blocking layer 150 is formed on the second surface S2 and the third surface S3 selectively with respect to the first surface S1.

As described above, according to the substrate processing method according to the second embodiment, the blocking layer 150 can be selectively formed on the second surface S2 and the third surface S3 as shown in the processes from step S201 to step S204.

Next, in step S205, as in step S105, the controller 9 forms the dielectric film 160 on the substrate W. FIG. 7B is a schematic cross-sectional view of the substrate W after the process of step S205.

In step S206, as in step S106, the controller 9 performs etching treatment on the substrate W. FIG. 7C is a schematic cross-sectional view of the substrate W after the process in step S206.

As described above, according to the substrate processing method according to the second embodiment, as shown in the processes from step S201 to step S206, the dielectric film 160 can be selectively formed on the dielectric film 110.

The processes from step S202 to step S206 or the processes from step S203 to step S206 may be repeated as one cycle. Thus, the film thickness of the dielectric film 160 formed on the first surface S1 can be increased.

When selectively forming the blocking layer 150 on the second surface S2 and the third surface S3, the substrate processing method according to the first embodiment (see FIG. 2 to 4C) supplies the second organic compound gas (see step S104) after supplying the first organic compound gas (see step S103). The substrate processing method according to the second embodiment (see FIG. 5 to 7C) supplies the first organic compound gas (see S204) after supplying the second organic compound gas (see S203). The supply of the first organic compound gas and the second organic compound gas is not limited to this. The first organic compound gas and the second organic compound gas may be supplied simultaneously. Even in this case, the blocking layer 150 can be selectively formed on the second surface S2 and the third surface S3.

The first organic compound gas may be supplied to the substrate W first (see step S103), and afterwords, the second organic compound gas may be supplied to the substrate W (see step S104). By previously adsorbing the first organic compound to the third surface S3 (see step S103) in this way, it is possible to previously reduce the adsorption site on the third surface S3. Therefore, when supplying the second organic compound gas to the substrate W (see step S104), it is possible to adsorb the second organic compound suitably to the second surface S2. That is, it is possible to form the blocking layer 150 suitably on the second surface S2.

Here, the blocking layer 150 formed by the substrate processing method according to the present embodiment and a blocking layer 150C formed by a substrate processing method according to a reference example will be described in comparison.

FIG. 8 is an example of a schematic cross-sectional view showing the state of the substrate W in the substrate processing method according to the reference example. In the substrate processing method according to the reference example, the blocking layer 150C includes a first self-assembled monolayer (first SAM) 151. That is, the blocking layer 150C is selectively formed only on the third surface S3.

Therefore, when forming the dielectric film 160 on the substrate W in the substrate processing method according to the reference example, the first surface S1 and the second surface S2 serve as film-formation start surfaces of the dielectric film 160. The dielectric film 160 grows from these film-formation start surfaces in the film thickness direction and the lateral direction. Therefore, as shown in FIG. 8, the dielectric film 160 is formed by X2 in the film thickness direction, and is formed by Y2 in the lateral direction from the boundary between the first surface S1 and the second surface S2 toward above the third surface S3.

On the other hand, in the substrate processing method according to the present embodiment, the blocking layer 150 includes the first self-assembled monolayer (first SAM) 151 and the second self-assembled monolayer (second SAM) 152. That is, the blocking layer 150 is selectively formed on the second surface S2 and the third surface S3.

Therefore, when forming the dielectric film 160 on the substrate W in the substrate processing method according to the present embodiment, the first surface S1 serves as a film-formation start surface of the dielectric film 160. The dielectric film 160 grows from this film-formation start surface in the film thickness direction and the lateral direction. Therefore, as shown in FIG. 4B, the dielectric film 160 is formed by X1 in the film thickness direction, and is formed by Y1 in the lateral direction from the boundary between the first surface S1 and the second surface S2 toward above the third surface S3.

Here, when the dielectric films 160 have the same film thickness (X1=X2), the film-formation amount Y1 in the lateral direction in the present embodiment is less than the film-formation amount Y2 in the lateral direction in the reference example (Y1<Y2). For example, the film-formation amount Y1 in the lateral direction in the present embodiment is less than the film-formation amount Y2 in the lateral direction in the reference example by the width of the barrier metal film 120. Thus, when forming the dielectric film 160, it is possible to inhibit the dielectric film 160 from overhanging the conductive film 130. Further, the controllability of the shape of the dielectric film 160 is improved.

Further, according to the substrate processing method according to the present embodiment, it is possible to reduce the number of times the etching treatment (S106 or S206) is performed, and/or the etching time. Thus, the impact of the etching treatment on the conductive film 130 can also be reduced.

Further, according to the substrate processing method according to the reference example, when etching the dielectric film 160 formed on the second surface S2 in the lateral direction, the dielectric film 160 formed on the first surface S1 is also etched in the film thickness direction. Therefore, when the step of forming the blocking layer 150C, the step of forming the dielectric film 160, and the etching step are regarded as one cycle, the number of cycles needed to form the dielectric film 160 having a desired film thickness on the first surface S1 might increase. Further, when the etching amount in the film thickness direction is equal to the etching amount in the lateral direction, the dielectric film 160 having a desired film thickness might not be formed on the first surface S1 even if the cycle is repeated.

On the other hand, according to the substrate processing method according to the present embodiment, the dielectric film 160 formed on the second surface S2 is formed to include the second self-assembled monolayer (second SAM) 152. Therefore, the dielectric film 160 formed on the second surface S2 has an etching resistance lower than that of the dielectric film 160 formed on the first surface S1. Therefore, in the etching treatment (S106 and S206), the dielectric film 160 formed on the second surface S2 can be etched in the lateral direction faster than the dielectric film 160 formed on the first surface S1 can be etched in the thickness direction. Thus, the dielectric film 160 having a desired film thickness can be formed on the first surface S1.

Although the substrate processing method according to the present embodiment by the substrate processing apparatus has been described above, the present disclosure is not limited to the above embodiments and other particulars, and various modifications and improvements are applicable within the scope of the present disclosure described in the claims.

According to one aspect, it is possible to provide a substrate processing method and a substrate processing apparatus for selectively forming a blocking layer.

What is claimed is:

1. A substrate processing method, comprising:
(a) preparing a substrate having a first surface including a dielectric film, a second surface including a metal nitride film, and a third surface including a conductive film, in different regions of a substrate surface;
(b) supplying a first organic compound containing any one of a thiol group, a phosphonic acid group, or a carboxylic acid group as a first reactive group to the substrate; and
(c) supplying a second organic compound containing a carbon-carbon double bond or a carbon-carbon triple bond as a second reactive group to the substrate,
wherein a blocking layer is formed on the second surface and the third surface selectively with respect to the first surface.

2. The substrate processing method according to claim 1,
wherein the (c) is performed after the (b).

3. The substrate processing method according to claim 1,
wherein the (b) is performed after the (c).

4. The substrate processing method according to claim 1,
wherein the (b) and the (c) are performed simultaneously.

5. The substrate processing method according to claim 1,
wherein the first organic compound adsorbs to the third surface selectively with respect to the first surface, and adsorbs to the third surface selectively with respect to the second surface, and
the second organic compound adsorbs to the second surface selectively with respect to the first surface, and adsorbs to the third surface selectively with respect to the first surface.

6. The substrate processing method according to claim 5,
wherein, in the (b), a first self-assembled monolayer is formed on the third surface,
in the (c), a second self-assembled monolayer is formed on the second surface and the third surface, and
the blocking layer includes the first self-assembled monolayer and the second self-assembled monolayer.

7. The substrate processing method according to claim 1,
wherein the metal nitride film is a barrier metal film provided between the dielectric film and the conductive film.

8. The substrate processing method according to claim 1,
wherein the metal nitride film is any one of TaN or TiN.

9. The substrate processing method according to claim 1,
wherein the first organic compound is any one of CH₃(CH₂)ₓCH₂SH (X is an integer of 0 to 18) or CH₃(CH₂)ₓCH₂COOH (X is an integer of 0 to 18), and
the second organic compound is any one of CH₃(CH₂)ₓCH=CH₂ (X is an integer of 0 to 18) or CH₃(CH₂)ₓC≡CH (X is an integer of 0 to 18).

10. A substrate processing apparatus, comprising:
a processing vessel;
a substrate support configured to support a substrate in the processing vessel;
a gas supply configured to supply a gas into the processing vessel; and
a controller including a processor and a memory,
wherein the controller is configured to perform:
(a) preparing a substrate having a first surface including a dielectric film, a second surface including a metal nitride film, and a third surface including a conductive film, in different regions of a substrate surface;
(b) supplying a first organic compound containing a thiol group, a phosphonic acid group, or a carboxylic acid group as a first reactive group to the substrate;
(c) supplying a second organic compound containing a carbon-carbon double bond or a carbon-carbon triple bond as a second reactive group to the substrate, and
wherein a blocking layer is formed on the second surface and the third surface selectively with respect to the first surface.
